(19) United States
(12) Patent Application Publication
(10) Pub. No.: US 2026/0268984 A1
(43) Pub. Date: Sep. 10, 2026

(54) MEMORY DEVICE AND METHOD OF READING MEMORY DEVICE

(71) Applicant: SK hynix Inc., Gyeonggi-do (KR)

(72) Inventors: Eun Woo JO, Gyeonggi-do (KR); Hyun Seob SHIN, Gyeonggi-do (KR)

(21) Appl. No.: 19/280,112

(22) Filed: Jul. 25, 2025

(30) Foreign Application Priority Data
Mar. 10, 2025 (KR) 10-2025-0030760

(51) Int. Cl. G11C 16/30; G11C 16/04; G11C 16/26; G11C 16/34

(52) U.S. Cl. CPC G11C 16/30; G11C 16/0483; G11C 16/26; G11C 16/3495

(57) ABSTRACT

A memory device includes a memory cell array and a peripheral circuit. The memory cell array includes a plurality of strings coupled between a bit line and a source line and each of the plurality of strings comprises a drain selection transistor coupled to a corresponding drain selection line, memory cells coupled to a plurality of word lines, and a source selection transistor coupled to a corresponding source selection line. The peripheral circuit is configured to apply a subthreshold gate voltage to a particular source selection line coupled to an unselected string among the plurality of strings, while applying a turn-off voltage to a particular drain selection line coupled to the unselected string, during at least a portion of a read interval in which a read pass voltage is applied to unselected word lines among the plurality of word lines.

### CROSS-REFERENCE TO RELATED APPLICATIONS

The present application claims priority under 35 U.S.C. §119(a) to Korean patent application number 10-2025-0030760 filed on Mar. 10, 2025, which is incorporated herein by reference in its entirety.

### BACKGROUND

### 1. Technical Field

Various embodiments generally relate to a memory device.

### 2. Related Art

Semiconductor devices are key components of electronic systems and have a wide range of modern applications. For example, they are used in technologies such as computing, communications, artificial intelligence, and memory. A semiconductor device may include components such as transistors, diodes, and integrated circuits (ICs).

The read performance of semiconductor memory devices plays a critical role in the processing speed and overall efficiency of memory systems, and also impacts the reliability of data retention. When high channel voltage is repeatedly applied to memory cells during read operations, the resulting stress can degrade data retention characteristics and reduce the lifespan of the cells. Therefore, a technical solution that improves both read performance and data stability is desirable.

### SUMMARY

In an embodiment, a memory device may include a memory cell array and a peripheral circuit. The memory cell array may include a plurality of strings coupled between a bit line and a source line and each of the plurality of strings may comprise a drain selection transistor coupled to a corresponding drain selection line, memory cells coupled to a plurality of word lines, and a source selection transistor coupled to a corresponding source selection line. The peripheral circuit may be configured to apply a subthreshold gate voltage to a particular source selection line coupled to an unselected string among the plurality of strings, while applying a turn-off voltage to a particular drain selection line coupled to the unselected string, during at least a portion of a read interval in which a read pass voltage is applied to unselected word lines among the plurality of word lines.

In an embodiment, a memory device may include a memory cell array and a peripheral circuit. The memory cell array may include a plurality of strings coupled between a bit line and a source line and each of the plurality of strings may comprise a drain selection transistor coupled to a corresponding drain selection line, memory cells coupled to a plurality of word lines, and a source selection transistor coupled to a corresponding source selection line. The peripheral circuit may be configured to reduce a voltage level of a channel of an unselected string among the plurality of strings to a level greater than a ground voltage during a channel voltage adjustment interval in a read operation.

In an embodiment, a method of reading a memory device may include: applying a turn-on voltage to a drain selection line coupled to an unselected string among a plurality of strings and a source selection line coupled to the unselected string, in a first interval; applying a turn-off voltage to the drain selection line and the source selection line, in a second interval following the first interval; and applying a subthreshold gate voltage to the source selection line while applying the turn-off voltage to the drain selection line, during at least a portion of a third interval following the second interval.

### BRIEF DESCRIPTION OF THE DRAWINGS

The present disclosure will be more fully understood from the following detailed description and the accompanying drawings. The description and the drawings are provided for illustrative purposes only and are not intended to limit the scope of the present disclosure.

FIG. 1 is a block diagram illustrating a memory device according to an embodiment of the present disclosure.

FIG. 2 is a circuit diagram illustrating a memory block included in a memory cell array according to an embodiment of the present disclosure.

FIG. 3 is a timing diagram of a read operation according to an embodiment of the present disclosure.

FIG. 4 is a timing diagram of a read operation according to an embodiment of the present disclosure.

FIG. 5 is a timing diagram of a read operation according to an embodiment of the present disclosure.

FIG. 6 is a flowchart of a read operation of a memory device according to an embodiment of the present disclosure.

### DETAILED DESCRIPTION

Various embodiments are described below in more detail with reference to the accompanying drawings. The present invention may, however, be embodied in different forms and should not be construed as limited to the embodiments set forth herein. Rather, these embodiments are provided so that this disclosure is thorough and complete and fully conveys the scope of the present invention to those skilled in the art. Moreover, reference herein to “an embodiment,” “another embodiment,” or the like is not necessarily to only one embodiment, and different references to any such phrases is not necessarily to the same embodiment(s). Throughout the disclosure, like reference numerals refer to like parts in the figures and embodiments of the present invention.

The invention can be implemented in numerous ways, including as a process; an apparatus; a system; a composition of matter; a computer program product embodied on a computer readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily configured to perform the task at a given time or a specific component that is manufactured to perform the task. As used herein, the term ‘processor’ refers to one or more devices, circuits, and/or processing cores suitable for processing data, such as computer program instructions.

A detailed description of embodiments of the invention is provided below along with accompanying figures that illustrate aspects of the invention. The invention is described in connection with such embodiments, but the invention is not limited to any embodiment. The scope of the invention is limited only by the claims, and the invention encompasses numerous alternatives, modifications and equivalents. Numerous specific details are set forth in the following description in order to provide a thorough understanding of the invention. These details are provided for the purpose of example; the invention may be practiced according to the claims without some or all of these specific details. For clarity, technical material that is known in technical fields related to the invention has not been described in detail so that the invention is not unnecessarily obscured.

Hereinafter, embodiments of the present disclosure will be described in more detail with reference to the accompanying drawings.

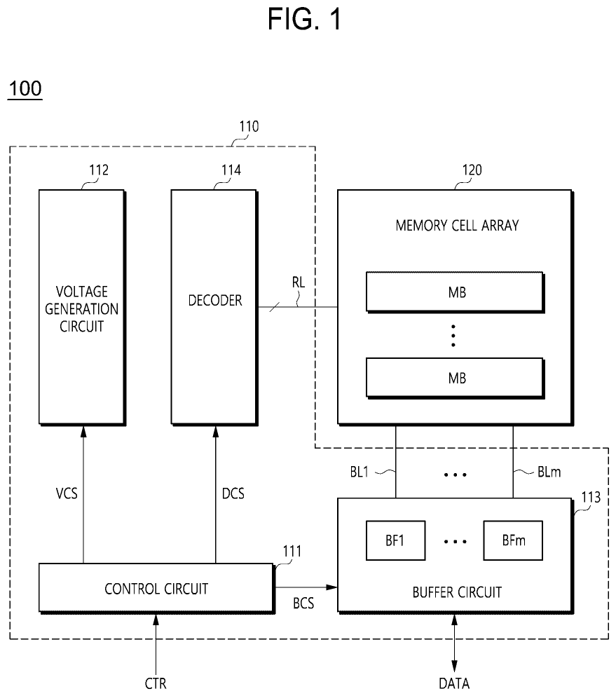

FIG. 1 is a block diagram illustrating a memory device 100 according to an embodiment of the present disclosure.

Referring to FIG. 1, the memory device 100 may operate in response to a control (signal(s)) CTR from an external controller (not shown). The memory device 100 may store data DATA received from the external controller (or host) by performing a program operation, and may output the stored data DATA to the controller (or host) by performing a read operation.

The memory device 100 may include a peripheral circuit 110 and a memory cell array 120.

The peripheral circuit 110 may store data in the memory cell array 120 and read data from the memory cell array 120. The peripheral circuit 110 may include a control circuit 111 a voltage generation circuit 112, a buffer circuit 113, and a decoder 114.

The control circuit 111 may control operations of the voltage generation circuit 112, the buffer circuit 113, and the decoder 114 to perform internal operations of the memory device 100, such as program operations, read operations, erase operations, and the like, in response to an external signal CTR received from the external controller. For example, to control the voltage generation circuit 112, the control circuit 111 may generate a voltage control signal VCS and output the voltage control signal VCS to the voltage generation circuit 112. To control the buffer circuit 113, the control circuit 111 may generate a buffer control signal BCS and output the buffer control signal BCS to the buffer circuit 113. To control the decoder 114, the control circuit 111 may generate a decoder control signal DCS and output the decoder control signal DCS to the decoder 114.

The voltage generation circuit 112 may generate various voltages (not shown) in response to the voltage control signal VCS and transmit the voltages to the buffer circuit 113, decoder 114, and other circuits of the memory device 100. The voltages output from the voltage generation circuit 112 may include: logic voltages that are transmitted to the control circuit 111, voltages that are transmitted to the buffer circuit 113 (such as a bit line voltage and an erase voltage), and voltages that are transmitted to the decoder 114 (such as a program voltage, a program pass voltage, a read voltage, a read pass voltages VP, a turn-on voltage, and a subthreshold gate voltage); a data read pass voltage supplied to a data path, a pump voltage supplied to a pump circuit, and various reference voltages.

The buffer circuit 113 may be coupled to the memory cell array 120 through bit lines BL1 to BLm. The buffer circuit 113 may include buffers BF1 to BFm coupled to the bit lines BL1 to BLm, respectively. The buffers BF1 to BFm may be coupled with memory cells (not shown) included in the memory cell array 120 through the bit lines BL1 to BLm. The buffers BF1 to BFm may receive and store data to be stored in the memory cells from the controller. The buffers BF1 to BFm may store data read from the memory cells for output to the controller. The buffers BF1 to BFm may operate simultaneously in response to the buffer control signal BCS, such that the memory cells coupled with the bit lines BL1 to BLm, respectively, may be accessed simultaneously.

The decoder 114 may be coupled to the memory cell array 120 through row lines RL. The decoder 114 may apply voltages to the row lines RL in response to the decoder control signal DCS. The row lines RL may include a drain selection line, word lines, and a source selection line, as will be described herein below.

The memory cell array 120 may include a plurality of memory blocks MB. Each memory block MB may include memory cells in which data DATA is stored. The memory cells may be selectively accessed through the row lines RL and the bit lines BL1 to BLm.

The peripheral circuit 110 may apply one or more read voltages to a selected word line coupled to memory cells on which a read operation is performed. While applying one or more read voltages to the selected word line, the peripheral circuit 110 may apply a read pass voltage VP to unselected word lines that are not the selected word line. As will be described later, during an interval in which the read pass voltage VP is applied to the unselected word lines, a voltage level of a channel of an unselected string among a plurality of strings coupled between a bit line and a source line may be kept relatively high. According to the present disclosure, the peripheral circuit 110 may reduce a voltage level of a channel of an unselected string to a level greater than a ground voltage during at least a portion of an interval in which the read pass voltage VP is applied to unselected word lines. Therefore, even in instances in which the voltage level of the channel of the unselected string is excessively boosted due to the advance of the boosting interval that raises the voltage levels of a plurality of word lines to the read pass voltage VP, the occurrence of hot carrier injection (HCI) in the channel of the unselected string can be suppressed, and as a result, data stability and read performance may be improved in accordance with the present disclosure.

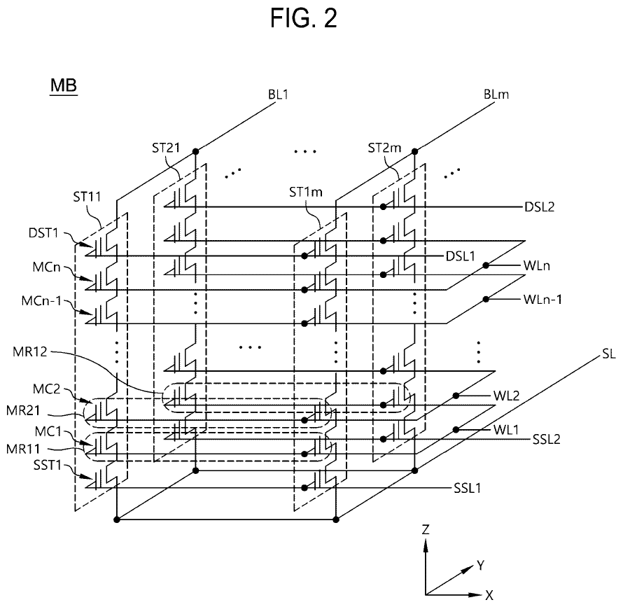

FIG. 2 is a circuit diagram illustrating a memory block MB included in the memory cell array 120 according to an embodiment of the present disclosure. The memory cell array 120 may include one or more memory blocks configured similarly to the memory block MB.

Referring to FIG. 2, the memory block MB may include strings ST11 to ST1m, ST21 to ST2m (where each of the ending alphanumeric characters represent a dimension of a group, e.g., the last alphanumeric character represents a group from 1 to m, where m is a whole number greater than 1). Each of the strings ST11 to ST1m, ST21 to ST2m may extend along a vertical direction (Z direction). Within the memory block MB, m strings may be arranged in a row direction (X direction). In FIG. 2, two strings are shown arranged in a column direction (Y direction), but this is for illustrative purposes only, and three or more strings may be arranged in the column direction (Y direction).

The strings ST11 to ST1m, ST21 to ST2m may be configured identically. For example, the string ST11 may include a source selection transistor SST1, memory cells MC1 to MCn, and a drain selection transistor DST1, coupled in series with each other between the source line SL and the bit line BL1. A source of the source selection transistor SST1 may be coupled to the source line SSL1, and a drain of the drain selection transistor DST1 may be coupled to the bit line BL1. The memory cells MC1 to MCn may be coupled in series with each other between the source selection transistor SST1 and the drain selection transistor DST1. In an embodiment, a plurality of source selection transistors may be coupled in series between the source line SL and the memory cell MC1. In an embodiment, a plurality of drain selection transistors may be coupled in series between the bit line BL1 and the memory cell MCn.

Source selection transistors at the same position in a vertical direction (for example, on a same horizontal plane) may be configured as shown with respect to FIG. 2 and described herein below. Specifically, the gates of the source selection transistors of strings arranged in the same row may be coupled to the same source selection line. For example, the gates of the source selection transistors of strings ST11 to ST1m in a first row may be coupled to a source selection line SSL1. For example, the gates of the source selection transistors of a second row of strings ST21 to ST2m may be coupled to a source selection line SSL2. In these instances, the source selection transistors also share a common horizontal dimension (e.g., a same row along direction X as shown in FIG. 2).

In an embodiment, source selection transistors of two or more rows of strings may be coupled in common to a single source selection line. For example, the source selection transistors of the first and second rows of strings ST11 to ST1m, ST21 to ST2m may be coupled in common to one source selection line, and the source selection transistors of the third and fourth rows of strings may be coupled in common to one source selection line.

Drain selection transistors at the same position in a vertical direction may be configured as shown below. Specifically, the gates of the drain selection transistors of strings arranged in the same row may be coupled to the same drain selection line. For example, the gates of the drain selection transistors of the strings ST11 to ST1m of the first row may be coupled to the drain selection line DSL1. For example, the gates of the drain selection transistors of the second row of the strings ST21 to ST2m may be coupled to the drain selection line DSL2.

Strings arranged in the same column may be coupled to the same bit line. For example, strings ST11, ST21 in a first column may be coupled to the bit line BL1. For example, strings ST1m, ST2m in an mth column may be coupled to the bit line BLm.

Gates of memory cells at the same position in a vertical direction may be coupled to the same word line. For example, in strings ST11 to ST1m and ST21 to ST2m, memory cells that are at the same position in a direction perpendicular to the memory cell MC1 may be coupled to the word line WL1.

Among the memory cells, memory cells coupled to the same word line in the same row may constitute one memory region. For example, memory cells coupled to the word line WL1 in the first row may constitute one memory region MR11. For example, memory cells coupled to the word line WL1 in the second row may constitute one memory region MR12. For example, memory cells coupled to word line WL2 in the first row may constitute one memory region MR21. Depending on the number of rows, each word line may be coupled to multiple memory regions. The memory cells constituting one memory region may be accessed simultaneously.

In an embodiment, the memory block MB may be further coupled to at least one dummy word line other than the word lines WL1 to WLn. In this instance, the memory block MB may further include dummy memory cells coupled to dummy word lines.

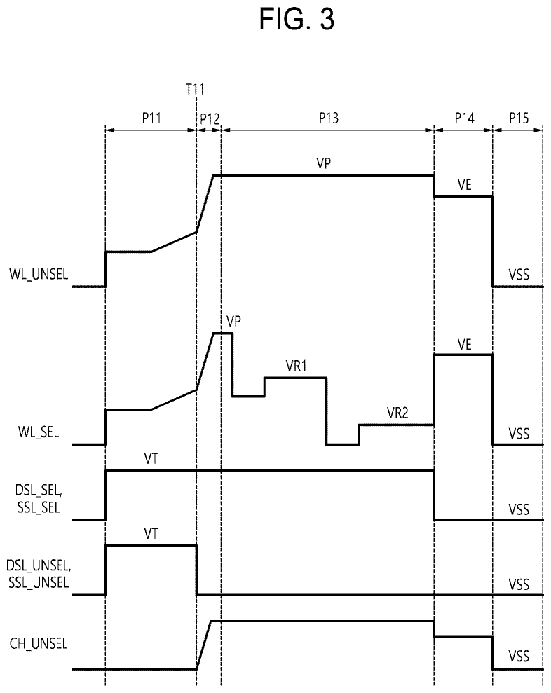

FIG. 3 is a timing diagram of a read operation according to an embodiment of the present disclosure.

Hereinafter, a drain selection line DSL_SEL coupled to a selected string and a source selection line SSL_SEL coupled to the selected string may be a drain selection line and a source selection line, respectively, coupled to a drain selection transistor and a source selection transistor included in the selected string. A drain selection line DSL_UNSEL coupled to an unselected string and a source selection line SSL_UNSEL coupled to the unselected string may be a drain selection line and a source selection line, respectively, coupled to a drain selection transistor and a source selection transistor included in the unselected string. A selected string may be a string among the strings coupled to a bit line that contains a memory cell in which a read operation is performed, and an unselected string may be a string among the strings coupled to the bit line, which is not the selected string. A selected word line WL_SEL may be a word line coupled to a target memory cell in which a read operation is performed among the memory cells included in the selected string. Unselected word lines WL_UNSEL may be word lines coupled to memory cells other than the target memory cell among the memory cells included in the selected string.

For example, in FIG. 2, when a target memory cell in which a read operation is performed is the memory cell MC1, a selected string may be the string ST11, and an unselected string may be the string ST21. Further, a selected word line WL_SEL is the word line WL1, and unselected word lines WL_UNSEL may be the word lines WL2 to WLn. Still further, a drain selection line DSL_SEL coupled to the selected string and a source selection line SSL_SEL coupled to the selected string may be the drain selection line DSL1 and the source selection line SSL1. Further, a drain selection line DSL_UNSEL coupled to the unselected string and a source selection line SSL_UNSEL coupled to the unselected string may be the drain selection line DSL2 and the source selection line SSL2.

Referring to FIG. 3, in an interval P11 (or, initialization interval) and an interval P12 (or, boosting interval), a voltage may be applied to the unselected word lines WL_UNSEL and the selected word line WL_SEL so that voltage levels of the unselected word lines WL_UNSEL and the selected word line WL_SEL rise to the read pass voltage VP. The voltage levels of the unselected word lines WL_UNSEL and the selected word line WL_SEL may be increased stepwise or gradually up to the read pass voltage VP.

In an interval P13 (or read interval), the voltage levels of the unselected word lines WL_UNSEL and the selected word line WL_SEL reach the read pass voltage VP. While the read pass voltage VP is applied to the unselected word lines WL_UNSEL, read voltages VR1, VR2 may be sequentially applied to the selected word line WL_SEL. In an embodiment, the number of read voltages applied in the interval P13 may vary.

In an interval P14 (or equalization interval), an equalization voltage VE may be applied to the unselected word lines WL_UNSEL and the selected word line WL_SEL to equalize voltage levels of the unselected word lines WL_UNSEL and the selected word line WL_SEL.

In an interval P15 (or discharge interval), the unselected word lines WL_UNSEL and the selected word line WL_SEL may be discharged to a ground voltage VSS.

In the interval P11, a turn-on voltage VT may be applied to the drain selection line DSL_SEL coupled to the selected string and the source selection line SSL_SEL coupled to the selected string. The turn-on voltage VT may be a voltage that can turn on the drain selection transistor and the source selection transistor coupled to the drain selection line DSL_SEL and the source selection line SSL_SEL coupled to the selected string, respectively. Therefore, in the interval P11, the drain selection transistor and the source selection transistor coupled to the drain selection line DSL_SEL and the source selection line SSL_SEL coupled to the selected string are turned on, and the channel of the selected string may be connected between the corresponding bit line and source line. As a result, in the interval P11, the channel of the selected string may be initialized by being discharged. In the intervals P12, P13, the drain selection line DSL_SEL coupled to the selected string and the source selection line SSL_SEL coupled to the selected string may continue to receive the turn-on voltage VT for a read operation.

In the intervals P14, P15, the drain selection line DSL_SEL coupled to the selected string and the source selection line SSL_SEL coupled to the selected string may be discharged. Therefore, in the intervals P14, P15, the drain selection transistor and the source selection transistor coupled to the drain selection line DSL_SEL and the source selection line SSL_SEL coupled to the selected string are turned off, and the channel of the selected string may be disconnected from the corresponding bit line and source line.

In the interval P11, the turn-on voltage VT may be applied to the drain selection line DSL_UNSEL coupled to the unselected string and the source selection line SSL_UNSEL coupled to the unselected string. Therefore, in the interval P11, the drain selection transistor and the source selection transistor coupled to the drain selection line DSL_UNSEL and the source selection line SSL_UNSEL coupled to the unselected string are turned on, and the channel CH_UNSEL of the unselected string may be connected between the corresponding bit line and source line. As a result, in the interval P11, the channel CH_UNSEL of the unselected string may be initialized by being discharged. In an embodiment, a turn-on voltage applied to the drain selection line DSL_SEL coupled to the selected string and the source selection line SSL_SEL coupled to the selected string may be different from a turn-on voltage applied to the drain selection line DSL_UNSEL coupled to the unselected string and the source selection line SSL_UNSEL coupled to the unselected string.

In the intervals P12 to P15, the drain selection line DSL_UNSEL coupled to the unselected string and the source selection line SSL_UNSEL coupled to the unselected string may be discharged to the ground voltage VSS. Therefore, in the intervals P12 to P15, the drain selection transistor and source selection transistor coupled to the drain selection line DSL_UNSEL coupled to the unselected string and the source selection line SSL_UNSEL coupled to the unselected string are turned off, and the channel CH_UNSEL of the unselected string may be disconnected from the corresponding bit line and source line.

As a result, at the end time point T11 of the interval P11, the channel CH_UNSEL of the unselected string may be disconnected from the corresponding bit line and source line, thereby reducing the capacitance between the channel CH_UNSEL of the unselected string and the word lines. Therefore, in the interval P12, the rising speed of the voltage levels of the unselected word lines WL_UNSEL and the selected word line WL_SEL may increase, so that the voltage levels of the unselected word lines WL_UNSEL and the selected word line WL_SEL can quickly reach the read pass voltage VP. In addition, in the interval P13, the channel CH_UNSEL of the unselected string may be at the boosted voltage level and may be less stressed by the read operation.

In an embodiment, the drain selection line DSL_SEL coupled to the selected string, the source selection line SSL_SEL coupled to the selected string, the drain selection line DSL_UNSEL coupled to the unselected string, and the source selection line SSL_UNSEL coupled to the unselected string may be applied with a predetermined turn-off voltage instead of the ground voltage VSS. The turn-off voltage may be a voltage that can turn off the drain selection transistor and the source selection transistor.

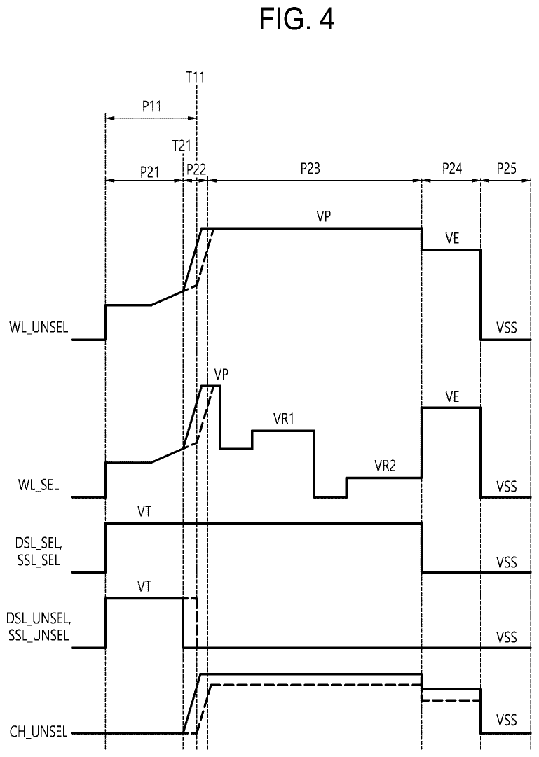

FIG. 4 is a timing diagram of a read operation according to an embodiment of the present disclosure. The waveforms shown as dotted lines in FIG. 4 may correspond to the operation of the embodiment described in reference to FIG. 3. The operations not described in relation to FIG. 4 below may be performed similarly to the operations described in reference to FIG. 3.

Referring to FIG. 4, in an interval P22, the drain selection line DSL_UNSEL coupled to the unselected string and the source selection line SSL_UNSEL coupled to the unselected string may be discharged to the ground voltage VSS. Therefore, in the interval P22, the drain selection transistor and the source selection transistor coupled to the drain selection line DSL_UNSEL and the source selection line SSL_UNSEL coupled to the unselected string are turned off, and the channel CH_UNSEL of the unselected string may be disconnected from the corresponding bit line and source line.

As a result, at the end time point T21 of the interval P21, the channel CH_UNSEL of the unselected string may be disconnected from the corresponding bit line and source line, thereby reducing the capacitance between the channel CH_UNSEL of the unselected string and the word lines. Therefore, in the interval P22, the rising speed of the voltage levels of the unselected word lines WL_UNSEL and the selected word line WL_SEL increases, so that the voltage levels of the unselected word lines WL_UNSEL and the selected word line WL_SEL can quickly reach the read pass voltage VP. In addition, in interval P22, the channel CH_UNSEL of the unselected string may be at the boosted voltage level and may be less stressed by the read operation.

Here, a duration of the interval P21 may be shorter than a duration of the interval P11 according to the embodiment of FIG. 3. In other words, the time point T21 at which the drain selection transistor and the source selection transistor coupled to the drain selection line DSL_UNSEL coupled to the unselected string and the source selection line SSL_UNSEL coupled to the unselected string are turned off, and the channel CH_UNSEL of the unselected string is disconnected from the corresponding bit line and source line, may be earlier than the time point T11 according to the embodiment of FIG. 3.

Therefore, in the interval P22, the time at which the voltage levels of the unselected word lines WL_UNSEL and the selected word line WL_SEL reach the read pass voltage VP may be earlier than in the embodiment of FIG. 3. As a result, the time for the entire read operation can be reduced, and the read performance of the memory device 100 can be improved.

However, in the interval P22, the amount of increase in the voltage levels of the unselected word lines WL_UNSEL and the selected word line WL_SEL may be larger than in the interval P12 according to the embodiment of FIG. 3. Therefore, in intervals P22, P23, the channel CH_UNSEL of the unselected string may be boosted to a higher voltage level than the embodiment in FIG. 3. As a result, HCI may occur in the channel CH_UNSEL of the unselected string, and degradation of the performance and reliability of the memory cell in the unselected string may be caused.

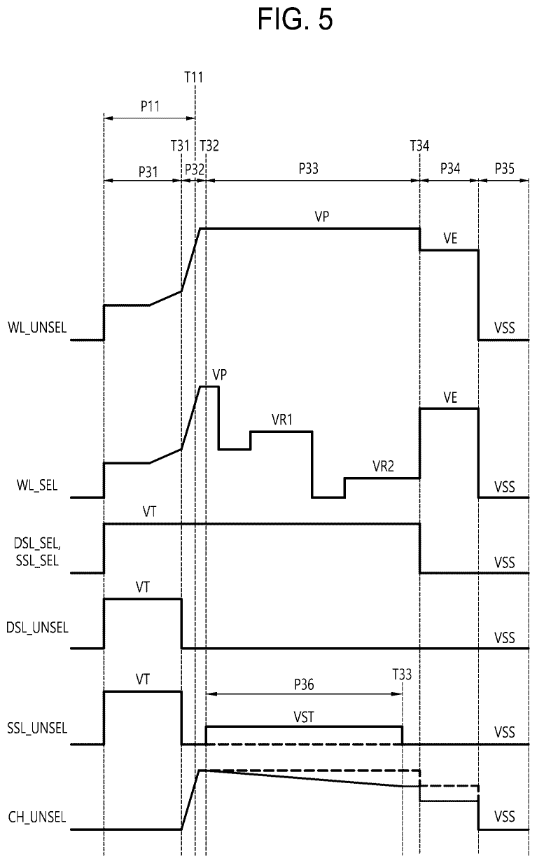

FIG. 5 is a timing diagram of a read operation according to an embodiment of the present disclosure. The waveforms shown as dotted lines in FIG. 5 may correspond to the operation of the embodiment described in reference to FIG. 4.

Referring to FIG. 5, in intervals P31 to P35, the unselected word lines WL_UNSEL, the selected word line WL_SEL, the drain selection line DSL_SEL coupled to the selected string, the source selection line SSL_SEL coupled to the selected string, the drain selection line DSL_UNSEL coupled to the unselected string may be controlled and operated similarly to the intervals P21 to P25 in FIG. 4. Therefore, the operation of the source selection line SSL_UNSEL coupled to the unselected string will be mainly described below.

The interval P33 may include an interval P36 (or a channel voltage adjustment interval).

In the interval P36, a subthreshold gate voltage VST of the source selection transistor may be applied to the source selection line SSL_UNSEL coupled to the unselected string. A start time point T32 of the interval P36 may be later than a time point at which the voltage levels of the unselected word lines WL_UNSEL and selected word line WL_SEL reach the read pass voltage VP. The start time point T32 of the interval P36 may be before the read voltages VR1, VR2 are applied to the selected word line WL_SEL. An end time point T33 of the interval P36 may be before a start time point T34 of the interval P34.

In an embodiment, the channel voltage adjustment interval may include a plurality of discontinuous intervals in the interval P33.

The subthreshold gate voltage VST may be a voltage between the ground voltage VSS (or a turn-off voltage of the source selection transistor) and a threshold voltage of the source selection transistor. Therefore, the source selection transistor of the unselected string is weakly turned on in response to the subthreshold gate voltage VST, and a voltage level of the channel CH_UNSEL of the unselected string may be reduced in the channel voltage adjustment interval P36. As a result, HCI can be suppressed in the channel CH_UNSEL of the unselected string.

In summary, the HCI occurrence in the channel CH_UNSEL of the unselected string is suppressed, and the rising characteristics of the read path voltage VP are improved compared to the embodiment of FIG. 3, thereby reducing the time for the entire read operation, and thus the read performance of the memory device 100 can be improved.

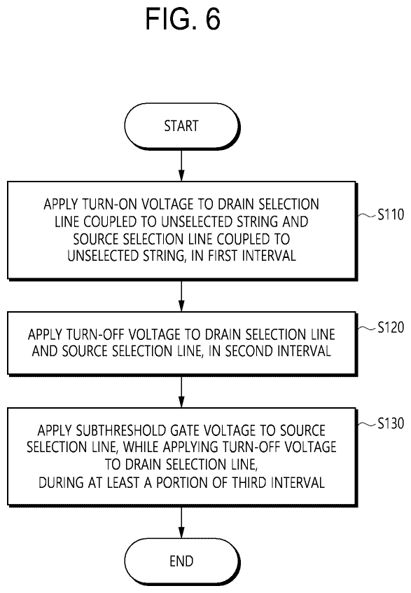

FIG. 6 is a flowchart of a read operation of the memory device 100 according to an embodiment of the present disclosure.

Referring to FIG. 6, in operation S110, the peripheral circuit 110 of FIG. 1 may apply the turn-on voltage VT to the drain selection line DSL_UNSEL coupled to the unselected string and the source selection line SSL_UNSEL coupled to the unselected string among a plurality of strings coupled between the bit line and the source line, in a first interval (or, initialization interval).

In operation S120, the peripheral circuit 110 may apply a turn-off voltage to the drain selection line DSL_UNSEL coupled to the unselected string and the source selection line SSL_UNSEL coupled to the unselected string, in a second interval (or boosting interval) following the first interval. The peripheral circuit 110 may raise the voltage levels of a plurality of word lines to the read pass voltage VP in the first and second intervals.

In operation S130, the peripheral circuit 110 may apply the subthreshold gate voltage VST to the source selection line SSL_UNSEL coupled to the unselected string, while applying the turn-off voltage to the drain selection line DSL_UNSEL coupled to the unselected string, during at least a portion of a third interval (or read interval), which follows the second interval. In the third interval, the peripheral circuit 110 may apply the one or more read voltages VR1, VR2 to the selected word line WL_SEL, while applying the read pass voltage VP to the unselected word lines WL_UNSEL.

While present disclosure contains many specifics, these should not be construed as limitations on the scope of any invention or of what may be claimed, but rather as descriptions of features that may be specific to particular embodiments of particular inventions. Certain features that are described in the present disclosure in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or a variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A memory device, comprising:
a memory cell array including a plurality of strings coupled between a bit line and a source line, each of the plurality of strings comprising a drain selection transistor coupled to a corresponding drain selection line, memory cells coupled to a plurality of word lines, and a source selection transistor coupled to a corresponding source selection line; and
a peripheral circuit configured to apply a subthreshold gate voltage to a particular source selection line coupled to an unselected string among the plurality of strings, while applying a turn-off voltage to a particular drain selection line coupled to the unselected string, during at least a portion of a read interval in which a read pass voltage is applied to unselected word lines among the plurality of word lines.

2. The memory device of claim 1, wherein the peripheral circuit is configured to raise voltage levels of the plurality of word lines to the read pass voltage in an initialization interval and a boosting interval before the read interval.

3. The memory device of claim 2, wherein the peripheral circuit is configured to apply a turn-on voltage to the particular drain selection line and the particular source selection line in the initialization interval.

4. The memory device of claim 2, wherein the peripheral circuit is configured to apply the turn-off voltage to the particular drain selection line and the particular source selection line in the boosting interval.

5. The memory device of claim 2, wherein the peripheral circuit is configured to apply a turn-on voltage to another particular drain selection line coupled to a selected string among the plurality of strings and another particular source selection line coupled to the selected string in the initialization interval, the boosting interval, and the read interval.

6. The memory device of claim 1, wherein the peripheral circuit is configured to apply one or more read voltages to a selected word line among the plurality of word lines in the read interval.

7. The memory device of claim 1, wherein the peripheral circuit is configured to equalize voltage levels of the plurality of word lines in an equalization interval that follows the read interval.

8. The memory device of claim 7, wherein an end time point of the at least a portion of the read interval is earlier than a start time point of the equalization interval.

9. The memory device of claim 7, wherein the peripheral circuit is configured to apply the turn-off voltage to drain selection lines respectively coupled to the plurality of strings and source selection lines respectively coupled to the plurality of strings in the equalization interval.

10. The memory device of claim 1, wherein the at least a portion of the read interval includes a plurality of discontinuous intervals in the read interval.

11. A memory device comprising:
a memory cell array including a plurality of strings coupled between a bit line and a source line, each of the plurality of strings comprising a drain selection transistor coupled to a corresponding drain selection line, memory cells coupled to a plurality of word lines, and a source selection transistor coupled to a corresponding source selection line; and
a peripheral circuit configured to reduce a voltage level of a channel of an unselected string among the plurality of strings to a level greater than a ground voltage during a channel voltage adjustment interval in a read operation.

12. The memory device of claim 11, wherein the peripheral circuit is configured to reduce the voltage level of the channel to the level greater than the ground voltage by controlling the channel such that a subthreshold current flows toward the source line while disconnecting the channel from the bit line.

13. The memory device of claim 11, wherein the peripheral circuit is configured to disconnect the channel from the bit line and the source line in a boosting interval before the channel voltage adjustment interval.

14. The memory device of claim 13, wherein the peripheral circuit is configured to discharge voltage levels of channels of the plurality of strings to the ground voltage by connecting the channels to the bit line and the source line in an initialization interval before the boosting interval.

15. The memory device of claim 14, wherein the peripheral circuit is configured to raise voltage levels of the plurality of word lines to a read pass voltage in the initialization interval and the boosting interval.

16. The memory device of claim 11, wherein the channel voltage adjustment interval is included in a read interval in which one or more read voltages are applied to a selected word line among the plurality of word lines while a read pass voltage is applied to unselected word lines among the plurality of word lines.

17. A method of reading a memory device, the method comprising:
applying a turn-on voltage to a drain selection line coupled to an unselected string among a plurality of strings and a source selection line coupled to the unselected string, in a first interval;
applying a turn-off voltage to the drain selection line and the source selection line, in a second interval following the first interval; and
applying a subthreshold gate voltage to the source selection line while applying the turn-off voltage to the drain selection line, during at least a portion of a third interval following the second interval.

18. The method of claim 17, further comprising raising voltage levels of a plurality of word lines to a read pass voltage, in the first interval and the second interval.

19. The method of claim 17, further comprising applying the turn-on voltage to a drain selection line coupled to a selected string among the plurality of strings and a source selection line coupled to the selected string, in the first interval to the third interval.

20. The method of claim 17, further comprising applying one or more read voltages to a selected word line while applying a read pass voltage to unselected word lines, in the third interval.
